(19) United States
(12) Patent Application Publication
(10) Pub. No.: US 2022/0252635 A1
(43) Pub. Date: Aug. 11, 2022

(54) MECHANICALLY-SENSITIVE SEMICONDUCTING TRIODE CAPACITOR

(71) Applicant: Kionix, Inc., Ithaca, NY (US)

(72) Inventor: Jonah DEWALL, Lansing, NY (US)

(21) Appl. No.: 17/591,077

(22) Filed: Feb. 2, 2022

Related U.S. Application Data
(60) Provisional application No. 63/146,328, filed on Feb. 5, 2021.

(51) Int. Cl. G01P 15/125; G01P 15/08; G01P 15/13

(52) U.S. Cl. CPC G01P 15/125; B81B 2201/0235; G01P 15/131; G01P 15/0802

(57) ABSTRACT

A sensor apparatus includes a base, a tap, a channel, and a gate. The tap is adjacent the base and electrically coupled to the base. The channel is between the tap and the base. The gate is adjacent the channel and electrically coupled to the channel. The gate is separated from the channel by a gap. At least a portion of a charge flow in the channel is substantially parallel or antiparallel to an electric field between the gate and the channel. A triode capacitor system includes a channel region, a gate region, and a processor. The gate region is separated from the channel region by a gap. The processor is coupled to a base contact, a tap contact, and a gate contact and configured to measure a distance of the gap based on a potential difference between the base contact and the tap contact.

### CROSS REFERENCE TO RELATED APPLICATION

This application claims priority to U.S. Provisional Application No. 63/146,328, filed Feb. 5, 2021, which is hereby incorporated herein in its entirety by reference.

### BACKGROUND

### Field

The present disclosure relates to sensor apparatuses and systems, for example, triode capacitor apparatuses and systems for measuring a distance of a free-space capacitive gap.

### Background

A microelectromechanical system (MEMS) can be fabricated using semiconductor device fabrication technologies. MEMS utilizes microelectronic processing techniques to reduce mechanical components down to the scale of microelectronics. MEMS offers the opportunity to integrate mechanical sensor elements and their associated signal processing electronics onto a single chip in a common manufacturing process. MEMS can be used for various devices including accelerometers, gyroscopes, inertial measurement units, digital micromirrors, optical switching units, pressure sensors, microphones, resonators, or magnetometers. For example, accelerometer elements constructed using MEMS include structures similar to a standard accelerometer: a proof-mass, restoring springs, a displacement transducer, some form of damping, and a case to which everything is attached. To provide the necessary electrical circuitry, such a MEMS accelerometer can be wire bonded to an Application Specific Integrated Circuit (ASIC). The MEMS accelerometer and ASIC can be packaged in a packaging unit typically constructed of three components: (1) a MEMS element that senses acceleration; (2) electronics included in an ASIC that transduces the MEMS element's response to acceleration into an electronic signal; and (3) a package that houses the MEMS element and the ASIC.

Many MEMS sensors rely on passive capacitive pickoffs to detect small displacements and motions because passive capacitive pickoffs are relatively simple to build and incorporate with complementary metal-oxide-semiconductor (CMOS) circuitry. However, inherent performance limitations of capacitive pickoffs indicate alternative technologies such as piezoelectric, optical, or active pickoffs may be more suitable. But piezoelectric and optical pickoffs are difficult to manufacture in standard MEMS processing and are expensive relative to their capacitive counterparts.

Active pickoffs couple micro-mechanical moving parts with active semiconductor devices such as transistors and diodes. Classes of active pickoffs include resonant gate transistors and resonant body transistors, which are typically used for micro-resonator devices. Such resonant transistor devices operate similarly to metal-oxide-semiconductor field-effect transistors (MOSFETs), but have sensitivity to the gate-channel proximity in addition to the gate-channel voltage.

Resonant transistor devices, like MOSFETs, achieve channel conduction by producing an inversion layer in the channel (i.e., a channel through which a charge current can pass between source and drain contacts). Creating an inversion layer requires an immense electric field. MOSFET devices typically have gate-channel gaps on the order of 10 nm or less and utilize high-permittivity dielectrics (e.g., high-κ dielectrics 3.9 times higher than free-space) in order to produce the strong electric field. Achieving such large electric fields in resonant transistor devices is difficult. Moving parts depend on low-permittivity free-space gaps, which reduces the achievable electric field strength compared to MOSFETs. Further, sub-micron gaps are difficult to manufacture consistently and can be problematic due to electromechanical pull-in and latching. Hence, resonant transistor devices are impractical sensors for a majority of MEMS devices.

### SUMMARY

Accordingly, there is a need to develop a MEMS sensor with active pickoff technology that operates with electric fields much smaller than its transistor-based counterparts and senses gaps on the order of microns rather than nanometers, and provide a MEMS sensor compatible with existing MEMS sensor designs and microfabrication processes.

In some embodiments, a sensor apparatus includes a base, a tap, a channel, and a gate. The tap is adjacent the base and electrically coupled to the base. The channel is between the tap and the base. The gate is adjacent the channel and electrically coupled to the channel, wherein the gate is separated from the channel by a gap. At least a portion of a charge flow in the channel is substantially parallel or antiparallel to an electric field between the gate and the channel.

In some embodiments, the gate includes a microelectromechanical system (MEMS) configured to adjust the gap between the gate and the channel. In some embodiments, the sensor apparatus further includes a processor coupled to the base, the tap, and the gate and configured to measure a distance of the gap between the gate and the channel based on a potential difference applied across the gap.

In some embodiments, in a first configuration, the channel is in a depletion mode and the electric field pervades within the channel. In some embodiments, the channel is a p-type semiconductor and a gate potential is greater than a channel potential. In some embodiments, the channel is an n-type semiconductor and a channel potential is greater than a gate potential. In some embodiments, a potential difference between the base and the tap is configured to be proportional to a distance of the gap between the gate and the channel. In some embodiments, the base, the tap, and the gate are configured to operate in a low-power configuration and are each held at an applied potential of zero.

In some embodiments, the gate is an n-type semiconductor or a conductor and held at a gate potential of about 1 V to about 10 V. In some embodiments, the electric field is vertically oriented and configured to pervade the channel along a vertical axis. In some embodiments, the electric field is horizontally oriented and configured to pervade the channel along a horizontal axis. In some embodiments, the electric field is radially oriented and configured to pervade the channel along a radial axis.

In some embodiments, the sensor apparatus includes an accelerometer, a gyroscope, a pressure sensor, a resonator, or a magnetometer. In some embodiments, the gap includes a dielectric. In some embodiments, the dielectric includes air.

In some embodiments, a triode capacitor system includes a channel region, a gate region, and a processor. The channel region includes a base contact and a tap contact. The gate region is adjacent the channel region and includes a gate contact. The gate region is separated from the channel region by a gap. The processor is coupled to the base contact, the tap contact, and the gate contact and configured to measure a distance of the gap based on a potential difference between the base contact and the tap contact. At least a portion of a current flow in the channel region is substantially parallel or antiparallel to an electric field between the gate region and the channel region.

In some embodiments, the base contact is electrically connected to a first portion of the channel region and the tap contact is electrically connected to a second portion of the channel region separate from the first portion. In some embodiments, the base contact is connected in series with a resistor. In some embodiments, a base node between the resistor and the channel region is connected to a complementary metal-oxide-semiconductor (CMOS) operational amplifier (op-amp). In some embodiments, the channel region is a p-type semiconductor and the gate region is an n-type semiconductor or a conductor. In some embodiments, the base contact is held at a base potential of about 0.8 V, the tap contact is held at a tap potential of about 0 V, and the gate contact is held at a gate potential of about 1.6 V to about 10 V.

In some embodiments, a method for measuring a gap between a gate region and a channel region in a sensor apparatus includes applying a gate potential, a base potential, and a tap potential in the sensor apparatus. The sensor apparatus includes a channel region, a gate region, and a processor. The channel region includes a base contact and a tap contact. The gate region is adjacent the channel region and includes a gate contact. The gate region is separated from the channel region by the gap. The processor is coupled to the base contact, the tap contact, and the gate contact. In some embodiments, the method further includes forming an electric field within the channel region in a depletion mode. At least a portion of a current flow in the channel region is substantially parallel or antiparallel to the electric field. In some embodiments, the method further includes measuring, by the processor, a distance of the gap based on a potential difference between the base contact and the tap contact.

In some embodiments, the method further includes adjusting the distance of the gap. In some embodiments, the gate region includes a microelectromechanical system (MEMS). In some embodiments, the method further includes calculating an impedance of the sensor apparatus in real-time based on the base potential. In some embodiments, the base contact is connected in series with a resistor. In some embodiments, the applying includes holding the gate potential, the base potential, and the tap potential at zero. In some embodiments, the measuring includes measuring the potential difference in real-time.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention.

FIG. 1 is a schematic illustration of a p-n junction apparatus, according to an exemplary embodiment.

FIG. 2 is a schematic circuit diagram of the p-n junction apparatus of FIG. 1.

FIG. 3 is a schematic illustration of a triode capacitor apparatus, according to an exemplary embodiment.

FIG. 4 is a schematic circuit diagram of the triode capacitor apparatus of FIG. 3.

FIG. 5 is a perspective schematic illustration of a sensor apparatus, according to an exemplary embodiment.

FIG. 6 is a partial cross-sectional schematic illustration of the sensor apparatus of FIG. 5.

FIG. 7 is a perspective schematic illustration of a sensor apparatus, according to an exemplary embodiment.

FIG. 8 is a partial cross-sectional schematic illustration of the sensor apparatus of FIG. 7.

FIG. 9 is a perspective schematic illustration of a sensor apparatus, according to an exemplary embodiment.

FIG. 10 is a partial cross-sectional schematic illustration of the sensor apparatus of FIG. 9.

FIG. 11 is a perspective schematic illustration of a sensor apparatus, according to an exemplary embodiment.

FIG. 12 is a partial cross-sectional schematic illustration of the sensor apparatus of FIG. 11.

FIG. 13 is a perspective schematic illustration of a sensor apparatus, according to an exemplary embodiment.

FIG. 14 is a partial cross-sectional schematic illustration of the sensor apparatus of FIG. 13.

FIG. 15 is a schematic circuit diagram of a p-type channel triode capacitor apparatus, according to an exemplary embodiment.

FIG. 16 is a schematic circuit diagram of a p-type channel triode capacitor apparatus, according to an exemplary embodiment.

FIG. 17 is a schematic circuit diagram of an n-type channel triode capacitor apparatus, according to an exemplary embodiment.

FIG. 18 is a schematic circuit diagram of an n-type channel triode capacitor apparatus, according to an exemplary embodiment.

FIG. 19 is a schematic circuit diagram of a differential p-type channel triode capacitor apparatus, according to an exemplary embodiment.

FIG. 20 illustrates a flow diagram for a sensor apparatus, according to an exemplary embodiment.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of this invention. The disclosed embodiment(s) merely exemplify the invention. The scope of the invention is not limited to the disclosed embodiment(s). The invention is defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “about” or “substantially” as used herein indicates the value of a given quantity that can vary based on a particular technology. Based on the particular technology, the term “about” or “substantially” can indicate a value of a given quantity that varies within, for example, 10-30% of the value (e.g., ±10%, ±20%, or ±30% of the value).

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, instructions, etc.

Exemplary P-N Junction Apparatus

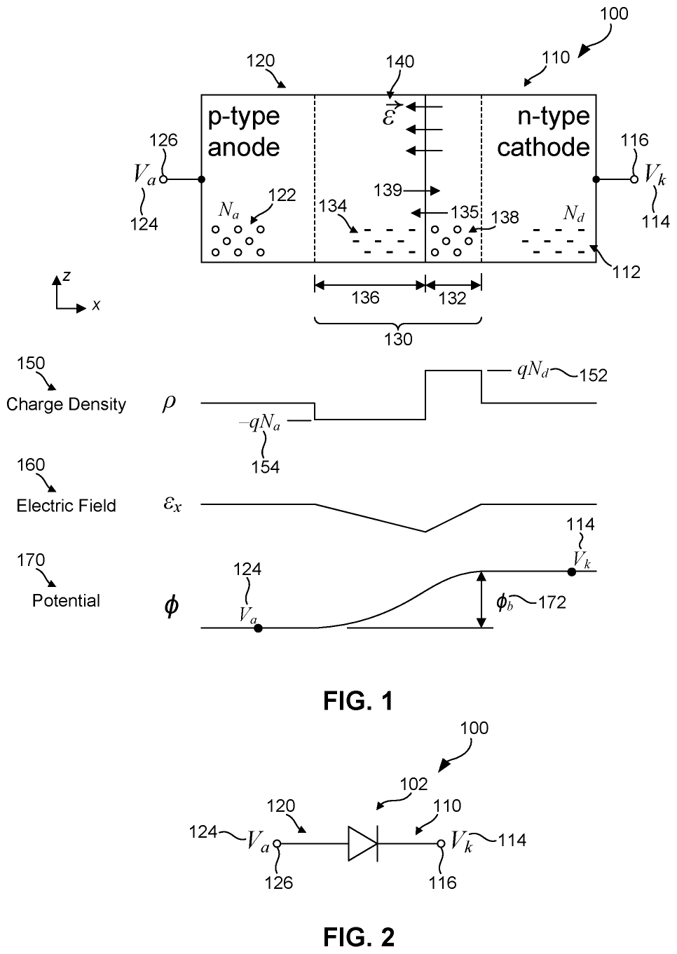

FIGS. 1 and 2 illustrate p-n junction apparatus 100, according to various exemplary embodiments.

FIG. 1 illustrates a schematic of p-n junction apparatus 100, according to an exemplary embodiment. FIG. 2 illustrates a schematic circuit diagram of p-n junction apparatus 100 as shown in FIG. 1. As shown in FIGS. 1 and 2, p-n junction apparatus 100 is a diode 102 with a built-in potential (ϕ_{b}) 172 and a junction is formed between a p-type anode 120 and an n-type cathode 110. Electrons 112 diffuse from the n-type cathode 110 to the p-type anode 120 and holes 122 diffuse from the p-type anode 120 to the n-type cathode 110. A depletion region 130 forms due to absent holes 139 or electrons 135. An electric field 140 forms from the positively charged 138 n-type cathode 110 to the negatively charged 134 p-type anode 120. Thermal equilibrium occurs when carrier (e.g., electrons, holes) diffusion 132, 136 is balanced by opposing drift 135, 139. The electric field 140 generates a potential barrier (e.g., built-in potential 172). Typically, the built-in potential 172 is about 0.7 V. Current flows (i.e., an inversion layer is formed) from the p-type anode 120 to the n-type cathode 110 if a difference between an anode potential (Vₐ) 124 and a cathode potential (Vₖ) 114 is greater than the built-in potential 172.

P-n junction apparatus 100 can include n-type cathode 110, depletion region 130, and p-type anode 120 and have charge density (ρ) 150, electric field (εₓ) 160, and potential (ϕ) 170. As shown in FIG. 1, n-type cathode 110 can include donor electrons (N_{d}) 112, cathode potential 114, and cathode contact 116. P-type anode 120 can include acceptor holes (Nₐ) 122, anode potential 124, and anode contact 126. Depletion region 130 can include cathode depletion region 132 and anode depletion region 136. Net electrons flow 135 is from cathode depletion region 132 to anode depletion region 136 and net holes flow 139 is from anode depletion region 136 to cathode depletion region 132. Cathode depletion region 132 can include net holes 138 and anode depletion region 136 can include net electrons 134. Net holes 138 and net electrons 134 form electric field 140 from cathode depletion region 132 to anode depletion region 136.

Charge density 150 in p-n junction apparatus 100, along a horizontal axis (i.e., “X-axis”) between p-type anode 120 and n-type cathode 110, includes donor charge density (qN_{d}) 152 in cathode depletion region 132 and acceptor charge density (−qNₐ) 154 in anode depletion region 136. Electric field 160, along the X-axis between p-type anode 120 and n-type cathode 110, indicates a maximum strength at an interface between cathode depletion region 132 and anode depletion region 136. Potential 170, along the X-axis between p-type anode 120 and n-type cathode 110, indicates built-in potential 172 in depletion region 130 between anode potential 124 and cathode potential 114.

Exemplary Triode Capacitor Apparatus

As discussed above, active pickoffs couple micro-mechanical moving parts with active semiconductor devices such as transistors and diodes. Classes of active pickoffs include resonant gate transistors and resonant body transistors, which are typically used for micro-resonator devices. Such resonant transistor devices operate similarly to metal-oxide-semiconductor field-effect transistors (MOSFETs), but have sensitivity to the gate-channel proximity in addition to the gate-channel voltage.

Resonant transistor devices, like MOSFETs, achieve channel conduction by producing an inversion layer in the channel (i.e., a channel through which a charge current can pass between source and drain contacts). Creating an inversion layer requires an immense electric field. MOSFET devices typically have gate-channel gaps on the order of 10 nm or less and utilize high-permittivity dielectrics (e.g., high-κ dielectrics 3.9 times higher than free-space) in order to produce the strong electric field. Achieving such large electric fields in resonant transistor devices is difficult. Moving parts depend on low-permittivity free-space gaps, which reduces the achievable electric field strength compared to MOSFETs. Further, sub-micron gaps are difficult to manufacture consistently and can be problematic due to electromechanical pull-in and latching. Hence, resonant transistor devices are impractical sensors for a majority of MEMS devices.

There is a need to develop a MEMS sensor with active pickoff technology that operates with electric fields much smaller than its transistor-based counterparts and senses gaps on the order of microns rather than nanometers. Further, there is a need to develop a MEMS sensor compatible with existing MEMS sensor designs and microfabrication processes.

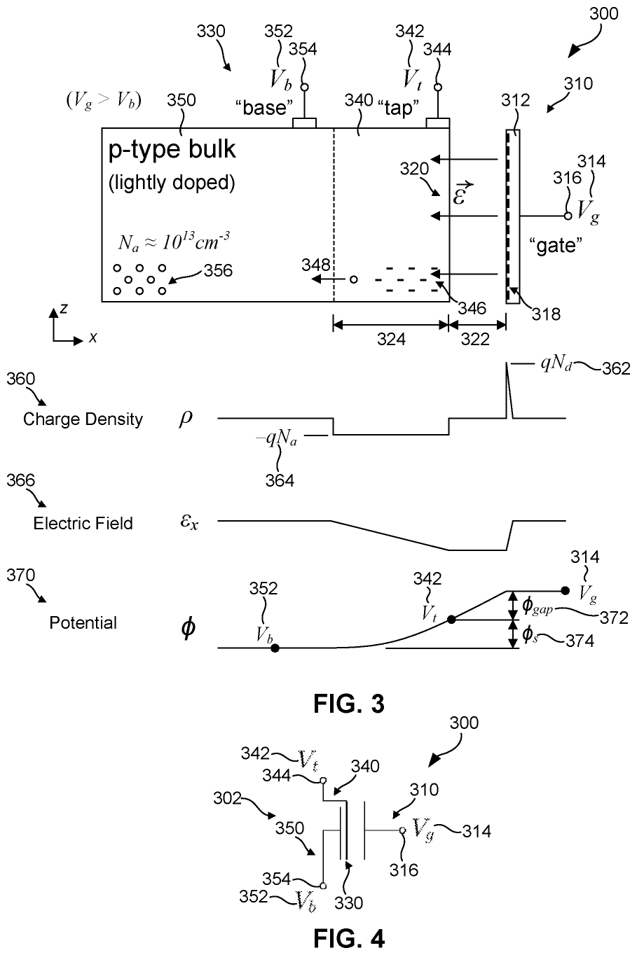

FIGS. 3 and 4 illustrate triode capacitor apparatus 300, according to various exemplary embodiments.

FIG. 3 illustrates a schematic of triode capacitor apparatus 300, according to an exemplary embodiment. FIG. 4 illustrates a schematic circuit diagram of triode capacitor apparatus 300 as shown in FIG. 3. Triode capacitor apparatus 300 is configured to be an active pickoff and mechanically-gated diode, where the mechanically-gated diode's flat-band voltage 372, 374, similar to a diode's built-in potential, is modulated by a displacement (i.e., gap 322) of a gate 312. Flat-band voltage 372, 374 is the potential required to bring channel region's 330 (i.e., semiconductor) band edges back to their flat band position from the bending position at the channel region 330 and gap 322 junction.

Unlike p-n junction apparatus 100 shown in FIGS. 1 and 2, triode capacitor apparatus 300 does not rely on achieving an inversion layer in the channel and, thus, can operate at much lower electric fields than resonator transistor devices. Triode capacitor apparatus 300 is a mechanically-gated diode rather than a mechanically-gated transistor, such as resonator transistor devices. Electric field 320 is much smaller than transistor-based counterparts (e.g., resonator transistor device) of triode capacitor apparatus 300. Channel region 330 of triode capacitor apparatus 300 remains in depletion mode 324 (i.e., not inversion mode) and is oriented relative to gate 312 such that conduction in channel region 330 is directly affected by electric field 320 within channel region 330 (e.g., tap 340). For example, a conduction path of channel region 330, along a horizontal axis (i.e., “X-axis”) between tap 340 and base 350, is at least partially aligned with electric field 320, causing electric field 320 to accelerate or decelerate charge within channel region 330. Channel region 330 functions as a diode whose potential barrier (i.e., flat-band potential 372, 374) is sensitive to a base-tap potential (ϕₛ) 374, a tap-gate potential (ϕ_{gap}) 372, and a distance of a tap-gate gap 322.

As shown in FIG. 3, triode capacitor apparatus 300 can include an n-type gate 312 and a lightly doped p-type bulk semiconductor 330 (i.e., channel region 330) to form a metal-oxide-semiconductor (MOS) capacitor. For example, lightly doped p-type bulk semiconductor 330 can be boron-doped silicon. Triode capacitor apparatus 300 can include a tap contact 344 contacting the lightly doped p-type bulk semiconductor 330 close to a capacitive gap 322 (i.e., tap 340) and a base contact 354 contacting the lightly doped p-type bulk semiconductor 330 outside of a depletion region 324 (i.e., base 350). If a gate potential (V_{g}) 314 is greater than a base potential (V_{b}) 352 (i.e., V_{g}>V_{b}), triode capacitor apparatus 300 produces a static potential (ϕₛ) 374 proportional to base-tap potential 352, 342, and a gap potential (ϕ_{gap}) 372 proportional to tap-gate potential 342, 314 and a distance of capacitive gap 322. When gate potential 314 is greater than base potential 352 (i.e., V_{g}>V_{b}), gate 312 has a positive charge and lightly doped p-type bulk semiconductor 330 has a negative charge. Lightly doped p-type bulk semiconductor 330 is in a depletion mode 324 (i.e., holes 348 move away from gate 312). Electric field 320 pervades into lightly doped p-type bulk semiconductor 330 causing a potential difference between base 350 and tap 340 (i.e., base-tap potential 352, 342). The potential formed between base 350 and tap 340 is static potential 374 (i.e., no current flow between base 350 and tap 340).

As shown in FIGS. 3 and 4, triode capacitor apparatus 300 is a mechanically-gated diode 302 with a flat-band potential 372, 374, which includes gap potential (ϕ_{gap}) 372 and static potential (ϕₛ) 374, and a junction is formed between gate 312 (e.g., n-type) and tap 340 (e.g., p-type) of channel region 330. Triode capacitor apparatus 300 is configured to provide a precise and accurate measurement of micro-mechanical capacitive gap 322. Triode capacitor apparatus 300 can include gate region 310, gap 322, and channel region 330 and have charge density (ρ) 360, electric field (εₓ) 366, and potential (ϕ) 370. Triode capacitor apparatus 300 is similar to a MOS capacitor in that each element or region of triode capacitor apparatus 300 corresponds to an element of a MOS capacitor: (1) gate region 310 (metal); (2) gap 322 (oxide); and (3) channel region 330 (semiconductor).

As shown in FIG. 3, gate region 310 can include n-type gate 312, gate potential (V_{g}) 314, gate contact 316, and donor electrons 318. Gate 312 is adjacent channel region 330 and electrically coupled to channel region 330. In some embodiments, gate 312 can be a doped semiconductor or a conductor. For example, gate 312 can include polysilicon, a metal, a conductive oxide, or any other suitable material capable of providing donor electrons 318. In some embodiments, gate 312 can be a p-type gate. For example, gate 312 can include a p-type semiconductor, for example, p-type polysilicon.

Channel region 330 can include tap 340 and base 350. Tap 340 can include depletion region 324, tap potential (Vₜ) 342, tap contact 344, and net electrons 346. Base 350 can include base potential (V_{b}) 352, base contact 354, and acceptor holes (Nₐ) 356. Gap 322 separates gate region 310 from channel region 330. As shown in FIG. 3, gap 322 can be a free-space capacitive gap between gate 312 and tap 340. Gap 322 can include electric field 320 between gate region 310 and channel region 330.

Donor electrons 318 of gate 312, acceptor holes 356 of channel region 330, and gate potential 314 being greater than base potential 352 (i.e., V_{g}>V_{b}) form electric field 320. Electric field 320 can pervade within channel region 330. For example, electric field 320 can pervade tap 340. A distance electric field 320 pervades into channel region 330 is proportional to a strength of electric field 320 and inversely proportional to a doping level of channel region 330. Depletion region 324 can form in tap 340 and include net electrons 346. Net holes flow 348 is from tap 340 to base 350.

Charge density 360 in triode capacitor apparatus 300, along a horizontal axis (i.e., “X-axis”) between p-type channel region 330 and n-type gate region 310, includes donor charge density (qN_{d}) 362 in gate region 310 and acceptor charge density (−qNₐ) 364 in depletion region 324. Electric field 366, along the X-axis between p-type channel region 330 and n-type gate region 310, indicates a maximum strength at gap 322. Also, electric field 366 pervades within depletion region 324 of tap 340 and electric field 366 forms within gate 312 due to gate potential 314 and donor electrons 318. Potential 370, along the X-axis between p-type channel region 330 and n-type gate region 310, indicates static potential 374 in depletion region 324 of tap 340 between base potential 352 and tap potential 342, and gap potential 372 in gap 322 between tap potential 342 and gate potential 314.

At least a portion of a charge flow in channel region 330 is substantially parallel or antiparallel to electric field 320. For example, a shortest path along channel region 330 between spatially-separated base contact 354 and tap contact 344 contains a portion that is substantially parallel or antiparallel to electric field 320 within channel region 330. A current between base contact 354 and tap contact 344 is accelerated or decelerated by electric field 320 within channel region 330. If gate potential 314 is greater than base potential 352 (i.e., V_{g}>V_{b}), triode capacitor apparatus 300 is in depletion mode, and electric field 320 pervades channel region 330. If base potential 352 is greater than gate potential 314 (i.e., V_{b}>V_{g}), triode capacitor apparatus 300 is in accumulation mode, and charge accumulates on a surface of channel region 330 and electric field 320 does not pervade channel region 330. In depletion mode, triode capacitor apparatus 300 has a non-zero net charge density 360 within a significant portion of channel region 330.

Charge density 360 produces electric field 320 within channel region 330. Electric field 320 within channel region 330 is proportional to a distance of gap 322, and the effect of electric field 320 on a charge current between tap contact 344 and base contact 354 is proportional to the distance of gap 322 if the charge current at least partially follows a path parallel or antiparallel to a direction of electric field 320. Triode capacitor apparatus 300 draws a measurable current between tap contact 344 and base contact 354 proportional to the distance of gap 322. Triode capacitor apparatus 300 has a mechanically sensitive impedance between tap contact 344 and base contact 354.

In some embodiments, triode capacitor apparatus 300 can be an accelerometer, a gyroscope, a pressure sensor, a resonator, or a magnetometer. In some embodiments, a base-gate potential 352, 314 can be enhanced by doping of gate region 310 and/or channel region 330. For example, a flat-band potential 372, 374 of 0.33 V can be achieved with doping gate 312 to N_{d}≈10¹⁴ cm⁻³, which for an applied base-gate potential 352, 314 of 1.6 V produces an effective potential of 1.93 V across triode capacitor apparatus 300 and enhances electric field 320 by 20%. In some embodiments, electric field 320 can be produced within gap 322 when base contact 354, tap contact 344, and gate contact 316 are held at ground. For example, a flat-band potential 372, 374 of 0.33 V produces an effective potential of 0.33 V across triode capacitor apparatus 300 and electric field 320 within gap 322 and channel region 330 for base potential 352, tap potential 342, and gate potential 314 of 0 V (i.e., ground).

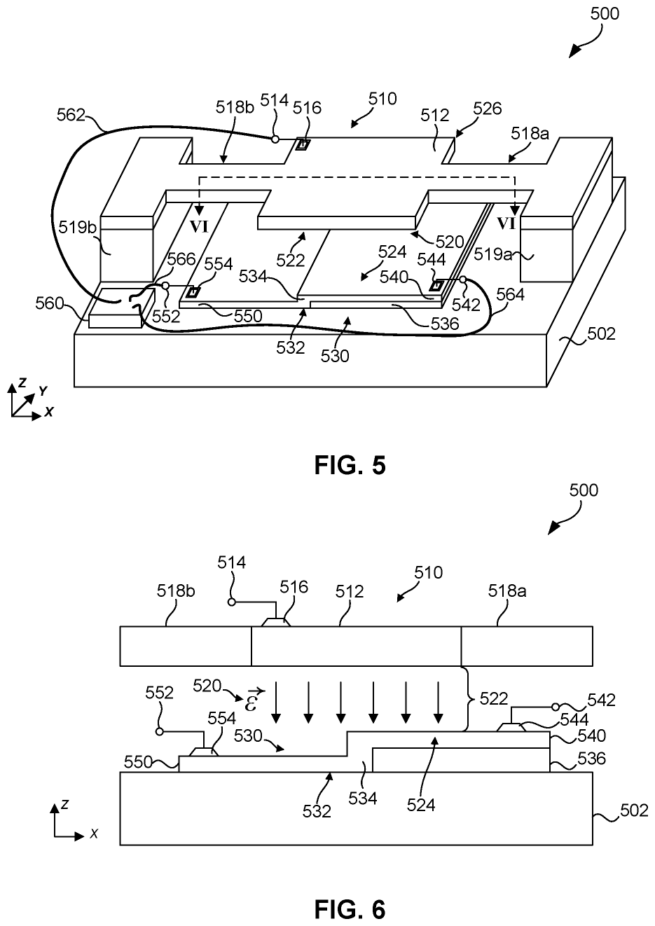

In some embodiments, gate 312 includes a microelectromechanical system (MEMS) configured to adjust gap 322 between gate 312 and channel region 330. For example, as shown in FIG. 5, gate 312 can be a planar MEMS plate with flexible support legs and capable of adjustment along a vertical axis (i.e., “Z-axis”). In some embodiments, triode capacitor apparatus 300 can include a processor coupled to base 350, tap 340, and/or gate 312 and configured to measure a distance of gap 322 based on a potential difference between gate region 310 and channel region 330. For example, the processor can be an Application Specific Integrated Circuit (ASIC) and measure base potential 352 and tap potential 342 and between tap potential 342 and gate potential 314 to determine the distance of gap 322. In some embodiments, in a first configuration, channel region 330 can be in a depletion mode 324 and electric field 320 can pervade within channel region 330. For example, as shown in FIG. 3, if gate potential 314 is greater than base potential 352 (i.e., V_{g}>V_{b}), channel region 330 is in a depletion mode 324 and electric field 320 pervades within channel region 330 (e.g., tap 340).

In some embodiments, channel region 330 can be a p-type semiconductor. For example, channel region 330 can be lightly doped silicon with Nₐ≈10¹³ cm⁻³. In some embodiments, channel region 330 can be an n-type semiconductor. For example, channel region 330 can be lightly doped silicon with N_{d}≈10¹³ cm⁻³. In some embodiments, channel region 330 can be a p-type semiconductor and gate 312 can be an n-type semiconductor or conductor and gate potential 314 can be greater than base potential 352 (i.e., V_{g}>V_{b}) such that a direction of electric field 320 is from gate 312 to channel region 330 (e.g., tap 340). For example, gate 312 can be held at gate potential 314 of about 1 V to about 10 V. In some embodiments, channel region 330 can be an n-type semiconductor and gate 312 can be a p-type semiconductor and base potential 352 can be greater than gate potential 314 (i.e., V_{b}>V_{g}) such that a direction of electric field 320 is from channel region 330 (e.g., tap 340) to gate 312.

In some embodiments, electric field 320 can be vertically oriented and configured to pervade channel region 330 along a vertical axis (i.e., Z-axis). In some embodiments, electric field 320 can be horizontally oriented and configured to pervade channel region 330 along a horizontal axis (i.e., X-axis). In some embodiments, electric field 320 can be radially oriented and configured to pervade channel region 330 along a radial axis (i.e., XY-plane). In some embodiments, triode capacitor apparatus 300 can be constructed in any or multiple angular orientations. For example, triode capacitor apparatus 300 can be constructed as a tri-axis sensor with a vertical orientation (i.e., Z-axis), a horizontal orientation (i.e., X-axis), and a depth orientation (i.e., “Y-axis”). In some embodiments, gap 322 includes a dielectric material. For example, gap 322 can include air.

Exemplary Sensor Apparatuses

FIGS. 5 through 14 illustrate alternatives of triode capacitor apparatus 300, according to various exemplary embodiments.

FIG. 5 illustrates a perspective schematic of sensor apparatus 500, according to an exemplary embodiment. FIG. 6 illustrates a partial cross-sectional schematic of sensor apparatus 500 as shown in FIG. 5. The embodiments of triode capacitor apparatus 300 shown in FIGS. 3 and 4 and the embodiments of sensor apparatus 500 shown in FIGS. 5 and 6 are similar.

Sensor apparatus 500 is configured to be an active pickoff and mechanically-gated diode with a vertically oriented (i.e., Z-axis) gate 512 with MEMS 526. As shown in FIGS. 5 and 6, sensor apparatus 500 can include substrate 502, gate region 510, gap 522, channel region 530, and processor 560. Sensor apparatus 500 is configured to provide a precise and accurate measurement of micro-mechanical capacitive gap 522.

Substrate 502 can support gate region 510, gap 522, channel region 530, and/or processor 560. In some embodiments, substrate 502 can be a semiconductor. For example, substrate 502 can be a lightly doped (e.g., p-type) silicon wafer capable of being microelectronically processed, diced, and packaged in a chip. In some embodiments, base 550 of channel region 530 can be connected to substrate 502. For example, charge flow 532 in base 550 can partially flow into and out of substrate 502. In some embodiments, substrate 502 can be insulating or a low conduction material. For example, substrate 502 can have a much lower doping level (e.g., intrinsic semiconductor) than channel region 530. In some embodiments, channel region 530 can be completely electrically isolated from substrate 502. For example, an intermediate insulating layer can be disposed between substrate 502 and channel region 530, for example, a silicon-on-insulator (SOI) wafer.

Gate region 510 can include gate 512, gate potential 514, gate contact 516, and MEMS 526. As shown in FIG. 5, MEMS 526 can include first and second gate supports 518a, 518b coupled to first and second gate platforms 519a, 519b disposed on substrate 502. Gate region 510 is adjacent channel region 530 and electrically coupled to channel region 530. Gate region 510 is separated from channel region 530 by gap 522. In some embodiments, gate 512 can be a doped semiconductor or a conductor. For example, gate 512 can include polysilicon (e.g., n-type, p-type), a metal, a conductive oxide, or any other suitable material capable of electrical conduction.

Channel region 530 can include charge flow (current flow) 532, insulating layer 536, tap 540, and base 550. Tap 540 can include tap potential 542 and tap contact 544. Base 550 can include base potential 552 and base contact 554. Gap 522 separates gate region 510 from channel region 530. As shown in FIG. 6, gap 522 can be a free-space capacitive gap between gate 512 and channel region 530 (e.g., tap 540). Similar to triode capacitor apparatus 300, a potential difference between gate potential 514 and base potential 552, e.g., V_{g}>V_{b} for an n-type gate 512 and a p-type channel region 530, forms electric field 520 within gap 522 and channel region 530. Electric field 520 can pervade within channel region 330 and affect charge flow 532 between tap contact 544 and base contact 554. For example, electric field 520 can pervade portion 534 of charge flow 532 which is substantially parallel or antiparallel to the direction of electric field 520 between gate region 510 and channel region 530, and cause charge flow 532 in portion 534 to accelerate or decelerate. Electric field 520 can pervade within channel region 530 and form depletion region 524 in tap 540 and/or base 550. A distance electric field 520 pervades into channel region 530 is proportional to a strength of electric field 520 and inversely proportional to a doping level of channel region 530. In some embodiments, as shown in FIG. 6, electric field 520 can form spatially within tap contact 544 and base contact 554. For example, electric field 520 can be localized to portion 534 of charge flow 532 which is substantially parallel or antiparallel to electric field 520.

Insulating layer 536 can be disposed on substrate 502 and spatially separate tap 540 from base 550. In some embodiments, insulating layer 536 can be a dielectric or any other electrically insulating material. For example, insulating layer 536 can include an oxide (e.g., SiOₓ, etc.), a nitride (e.g., SiNₓ, Si₃N₄, etc.), a glass (e.g., SOG, PSG, BPSG), a polymer (e.g., PTFE, PEEK, PMMA, photoresist, etc.), or any combination thereof. In some embodiments, insulating layer 536 and/or channel region 530 can be grown, deposited, patterned, and/or etched on substrate 502 with microelectronic fabrication processes. For example, insulating layer 536 can be grown or deposited on substrate 502 and channel region 530 can be subsequently grown or deposited on insulating layer 536 and substrate 502 using standard microfabrication techniques.

Processor 560 is configured to measure a distance of gap 522 based on a potential difference between base contact 554 and tap contact 544. Processor 560 can be coupled to gate contact 516, tap contact 544, and base contact 554. For example, as shown in FIG. 5, processor 560 can be coupled to gate contact 516, tap contact 544, and base contact 554 via first control signal 562, second control signal 564, and third control signal 566, respectively. In some embodiments, processor 560 can be an Application Specific Integrated Circuit (ASIC).

Similar to triode capacitor apparatus 300, channel region 530 of sensor apparatus 500 remains in depletion mode 524 (i.e., not inversion mode) and is oriented relative to gate 512 such that charge flow 532 in channel region 530 is directly affected by electric field 520 within channel region 530 (i.e., tap 540). For example, portion 534 of charge flow 532 of channel region 530, along a vertical axis (i.e., Z-axis) between base 550 and tap 540, is at least partially aligned with electric field 520, causing electric field 520 to accelerate or decelerate charge within channel region 530. Channel region 530 functions as a diode whose potential barrier (i.e., flat-band potential 372, 374 as shown in FIG. 3) is sensitive to a base-tap potential 552, 542 (i.e., static potential (ϕₛ) 374 as shown in FIG. 3), a tap-gate potential 542, 514 (i.e., gap potential (ϕ_{gap}) 372 as shown in FIG. 3), and a distance of gap 522.

Charge flow (current flow) 532 between base contact 554 and tap contact 544 is accelerated or decelerated by electric field 520 within channel region 530. If gate potential 514 is greater than base potential 552 (i.e., V_{g}>V_{b}), for an n-type gate 512 and a p-type channel region 530, sensor apparatus 500 is in depletion mode and electric field 520 pervades channel region 530. If base potential 552 is greater than gate potential 514 (i.e., V_{b}>V_{g}), for an n-type gate 512 and a p-type channel region 530, sensor apparatus 500 is in accumulation mode and charge accumulates on a surface of channel region 530 and electric field 520 does not pervade channel region 530. In depletion mode, sensor apparatus 500 has a non-zero net charge density within a significant portion of channel region 530, for example, portion 534 of charge flow 532. Sensor apparatus 500 draws a measurable current between tap contact 544 and base contact 554 proportional to the distance of gap 522. Sensor apparatus 500 has a mechanically sensitive impedance between tap contact 544 and base contact 554.

In some embodiments, sensor apparatus 500 can be an accelerometer, a gyroscope, a pressure sensor, a resonator, or a magnetometer. In some embodiments, a base-gate potential 552, 514 can be enhanced by doping of gate region 510 and/or channel region 530. For example, a flat-band potential of 0.33 V can be achieved with doping gate 512 to N_{d}≈10¹⁴ cm⁻³, which for an applied base-gate potential 552, 514 of 1.6 V produces an effective potential of 1.93 V across sensor apparatus 500 and enhances electric field 520 by 20%. In some embodiments, electric field 520 can be produced within gap 522 when base contact 554, tap contact 544, and gate contact 516 are held at ground. For example, a flat-band potential of 0.33 V produces an effective potential of 0.33 V across sensor apparatus 500 and electric field 520 within gap 522 and channel region 530 for base potential 552, tap potential 542, and gate potential 516 of 0 V (i.e., ground).

In some embodiments, channel region 530 can be a p-type semiconductor in order to form an n-type channel (i.e., electrons) for charge flow 532. For example, channel region 530 can be lightly doped (e.g., phosphorus, arsenic, antimony, bismuth) silicon with an acceptor concentration of about Nₐ≈10¹³ cm⁻³ to about Nₐ≈10¹⁵ cm⁻³. In some embodiments, channel region 530 can be an n-type semiconductor in order to form a p-type channel (i.e., holes) for charge flow 532. For example, channel region 530 can be lightly doped (e.g., boron, aluminum, indium, gallium) silicon with a donor concentration of about N_{d}≈10¹³ cm⁻³ to about N_{d}≈10¹⁵ cm⁻³. In some embodiments, channel region 530 can be a p-type semiconductor and gate 512 can be an n-type semiconductor or a conductor, and gate potential 514 can be greater than base potential 552 (i.e., V_{g}>V_{b}) such that a direction of electric field 520 is from gate 512 to channel region 530 (e.g., tap 540). For example, gate 512 can be held at gate potential 514 of about 1 V to about 10 V. In some embodiments, channel region 530 can be an n-type semiconductor and gate 512 can be a p-type semiconductor, and base potential 552 can be greater than gate potential 514 (i.e., V_{b}>V_{g}) such that a direction of electric field 520 is from channel region 530 (e.g., tap 540) to gate 512.

In some embodiments, electric field 520 can be vertically oriented and configured to pervade channel region 530 along a vertical axis (i.e., Z-axis). In some embodiments, electric field 520 can be horizontally oriented and configured to pervade channel region 530 along a horizontal axis (i.e., X-axis). In some embodiments, electric field 520 can be radially oriented and configured to pervade channel region 530 along a radial axis (i.e., XY-plane). In some embodiments, sensor apparatus 500 can be constructed in any or multiple angular orientations. For example, sensor apparatus 500 can be constructed as a tri-axis sensor with a vertical orientation (i.e., Z-axis), a horizontal orientation (i.e., X-axis), and a depth orientation (i.e., “Y-axis”). In some embodiments, gap 522 includes a dielectric material. For example, gap 522 can include air.

In some embodiments, base contact 554 can be connected in series with a resistor. For example, a base node between the resistor and channel region 530 can be connected to a complementary metal-oxide-semiconductor (CMOS) operational amplifier (op-amp) configured to measure the base node potential. In some embodiments, channel region 530 is a p-type semiconductor and gate region 510 is an n-type semiconductor or a conductor. For example, base contact 554 can be held at base potential 552 of about 0.8 V, tap contact 544 can be held at tap potential 542 of about 0 V (i.e. ground), and gate contact 516 can be held at gate potential 514 of about 1.6 V to about 10 V to allow base contact 554 and tap contact 544 to be CMOS-compatible and gate contact 516 to be a relatively high fixed gate potential 514.

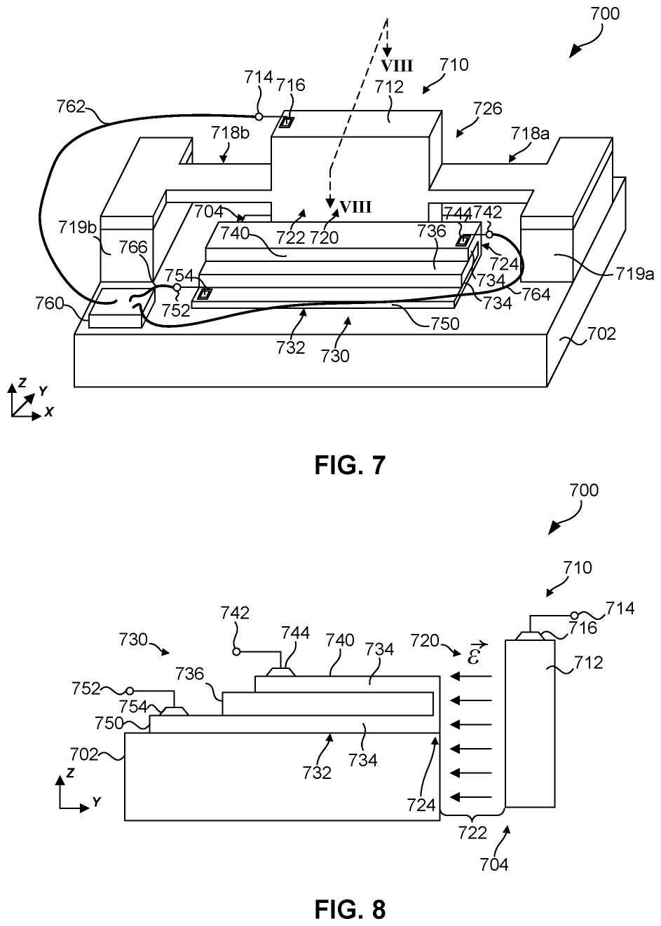

FIG. 7 illustrates a perspective schematic of sensor apparatus 700, according to an exemplary embodiment. FIG. 8 illustrates a partial cross-sectional schematic of sensor apparatus 700 as shown in FIG. 7. The embodiments of sensor apparatus 500 shown in FIGS. 5 and 6 and the embodiments of sensor apparatus 700 shown in FIGS. 7 and 8 are similar. Similar reference numbers are used to indicate similar features of the embodiments of sensor apparatus 500 shown in FIGS. 5 and 6 and the similar features of the embodiments of sensor apparatus 700 shown in FIGS. 7 and 8. Description of sensor apparatus 700 is omitted in the interest of brevity. One difference between the embodiments of sensor apparatus 500 shown in FIGS. 5 and 6 and the embodiments of sensor apparatus 700 shown in FIGS. 7 and 8 is that sensor apparatus 700 has a depth oriented (i.e., Y-axis) electric field 720, gap 722, and gate 712 disposed (suspended) in trench 704 formed in substrate 702, and channel region 730 includes a vertical stack (i.e., Z-axis) of base 750, insulating layer 736, and tap 740 with depletion region 724 between tap 740 and base 750.

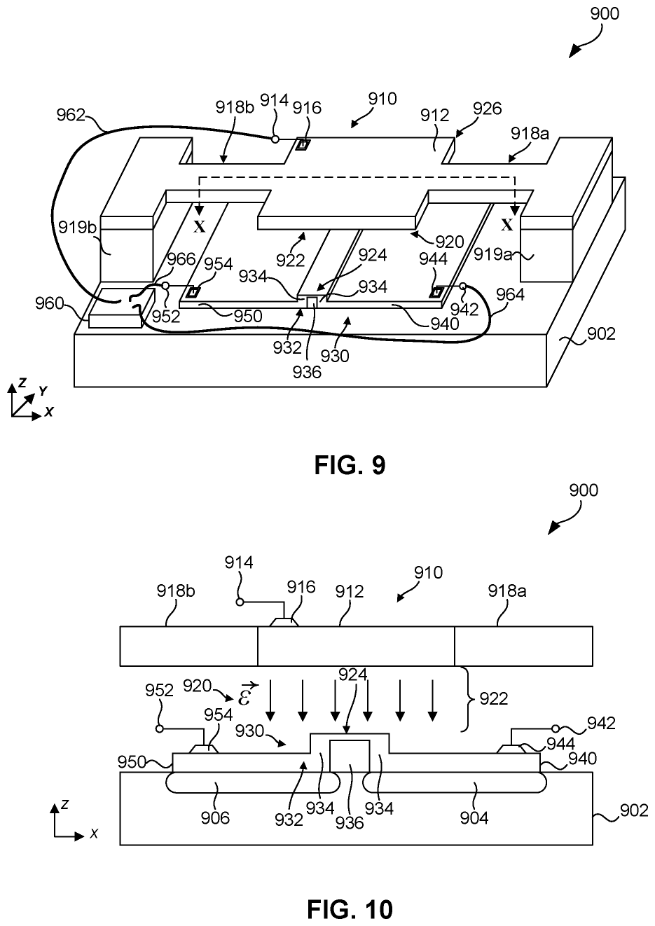

FIG. 9 illustrates a perspective schematic of sensor apparatus 900, according to an exemplary embodiment. FIG. 10 illustrates a partial cross-sectional schematic of sensor apparatus 900 as shown in FIG. 9. The embodiments of sensor apparatus 500 shown in FIGS. 5 and 6 and the embodiments of sensor apparatus 900 shown in FIGS. 9 and 10 are similar. Similar reference numbers are used to indicate similar features of the embodiments of sensor apparatus 500 shown in FIGS. 5 and 6 and the similar features of the embodiments of sensor apparatus 900 shown in FIGS. 9 and 10. Description of sensor apparatus 900 is omitted in the interest of brevity. One difference between the embodiments of sensor apparatus 500 shown in FIGS. 5 and 6 and the embodiments of sensor apparatus 900 shown in FIGS. 9 and 10 is that channel region 930 of sensor apparatus 900 has a FinFET (i.e., wrap around) design such that depletion region 924 wraps around an outer surface of insulating layer 936, and substrate 902 includes a tap p-well 904 disposed (e.g., implanted) below tab 940 and a base p-well 906 disposed (e.g., implanted) below base 950 for electrical isolation of charge flow 932 between tap contact 944 and base contact 954 from substrate 902.

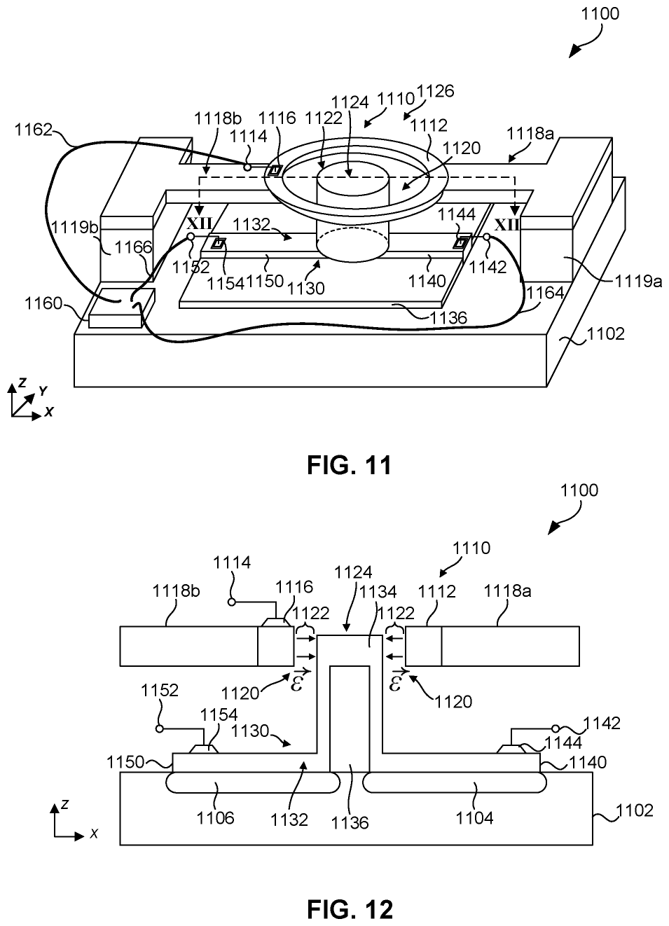

FIG. 11 illustrates a perspective schematic of sensor apparatus 1100, according to an exemplary embodiment. FIG. 12 illustrates a partial cross-sectional schematic of sensor apparatus 1100 as shown in FIG. 11. The embodiments of sensor apparatus 500 shown in FIGS. 5 and 6 and the embodiments of sensor apparatus 1100 shown in FIGS. 11 and 12 are similar. Similar reference numbers are used to indicate similar features of the embodiments of sensor apparatus 500 shown in FIGS. 5 and 6 and the similar features of the embodiments of sensor apparatus 1100 shown in FIGS. 11 and 12. Description of sensor apparatus 1100 is omitted in the interest of brevity. One difference between the embodiments of sensor apparatus 500 shown in FIGS. 5 and 6 and the embodiments of sensor apparatus 1100 shown in FIGS. 11 and 12 is that sensor apparatus 1100 has a radially oriented (i.e., XY-plane) electric field 1120, gap 1122, and gate 1112 shaped in the form of a ring, channel region 1130 has a FinFET (i.e., wrap around) design such that depletion region 1124 wraps around an outer surface of insulating layer 1136, and substrate 1102 includes a tap p-well 1104 disposed (e.g., implanted) below tab 1140 and a base p-well 1106 disposed (e.g., implanted) below base 1150 for electrical isolation of charge flow 1132 between tap contact 1144 and base contact 1154 from substrate 1102.

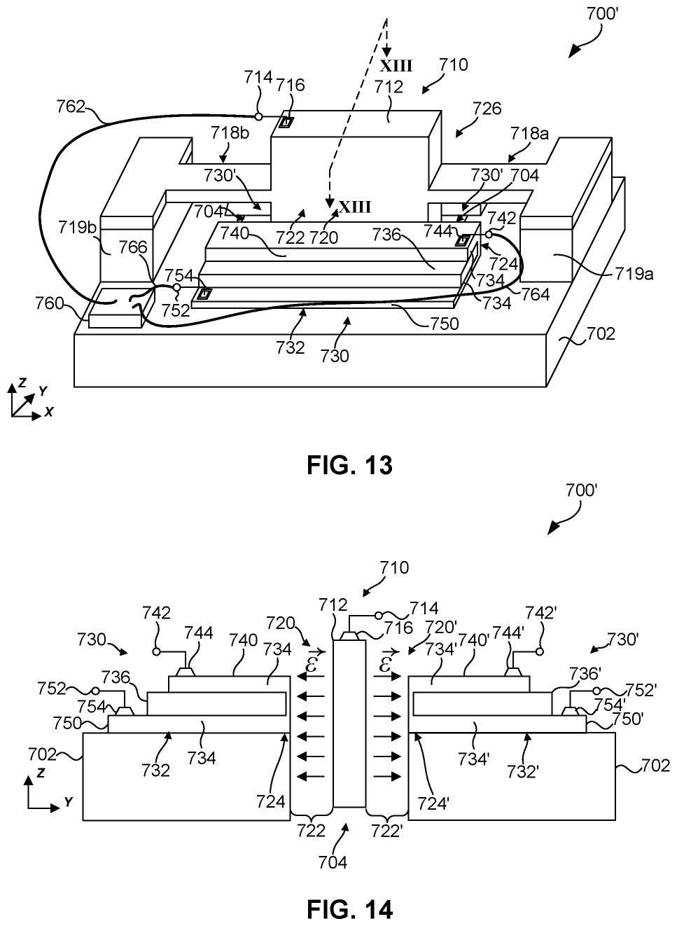

FIG. 13 illustrates a perspective schematic of sensor apparatus 700′, according to an exemplary embodiment. FIG. 14 illustrates a partial cross-sectional schematic of sensor apparatus 700′ as shown in FIG. 13. The embodiments of sensor apparatus 500 shown in FIGS. 5 and 6 and the embodiments of sensor apparatus 700′ shown in FIGS. 13 and 14 are similar. Similar reference numbers are used to indicate similar features of the embodiments of sensor apparatus 500 shown in FIGS. 5 and 6 and the similar features of the embodiments of sensor apparatus 700′ shown in FIGS. 13 and 14. Description of sensor apparatus 700′ is omitted in the interest of brevity. One difference between the embodiments of sensor apparatus 500 shown in FIGS. 5 and 6 and the embodiments of sensor apparatus 700′ shown in FIGS. 13 and 14 is that sensor apparatus 700′ has a differential depth oriented (i.e., Y-axis) dual electric fields 720, 720′, dual gaps 722, 722′, and gate 712 disposed (suspended) in trench 704 formed in substrate 702, and dual oppositely facing (i.e., mirror image about Z-axis) channel regions 730, 730′, each of which includes a vertical stack (i.e., Z-axis) of base 750, 750′, insulating layer 736, 736′, and tap 740, 740′ with depletion region 724, 724′ between tap 740, 740′ and base 750, 750′, respectively.

Exemplary Triode Capacitor Apparatuses

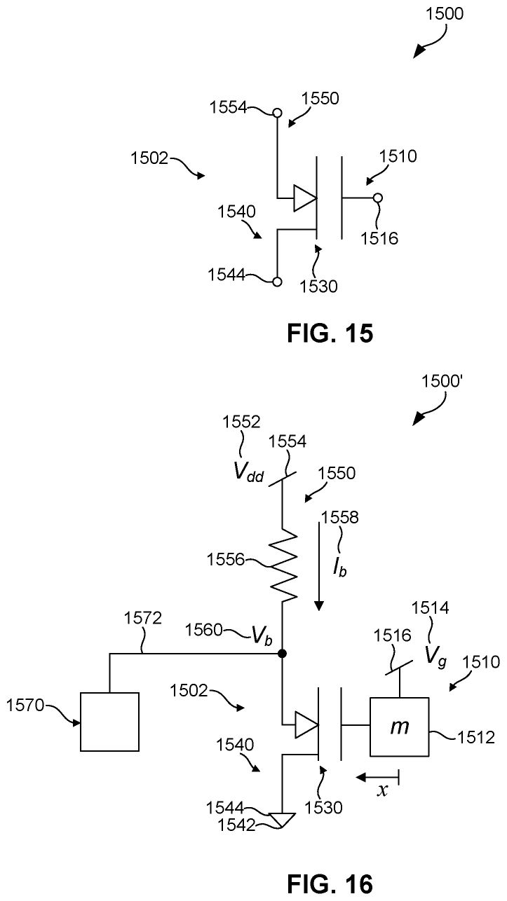

FIGS. 15 through 19 illustrate alternatives of triode capacitor apparatus 300 and sensor apparatus 500, according to various exemplary embodiments.

FIG. 15 illustrates a schematic circuit diagram of p-type channel triode capacitor apparatus 1500, according to an exemplary embodiment. The embodiments of triode capacitor apparatus 300 shown in FIGS. 3 and 4 and the embodiments of p-type channel triode capacitor apparatus 1500 shown in FIG. 15 are similar. The embodiments of sensor apparatus 500 shown in FIGS. 5 and 6 and the embodiments of p-type channel triode capacitor apparatus 1500 shown in FIG. 15 are similar.

Similar to triode capacitor apparatus 300 and sensor apparatus 500, p-type channel triode capacitor apparatus 1500 is configured to be a mechanically-gated diode 1502. As shown in FIG. 15, p-type channel triode capacitor apparatus 1500 includes n-type gate region 1510 and p-type channel region 1530. Gate region 1510 includes gate 1512 (not shown), gate potential 1514 (not shown), and gate contact 1516. Channel region 1530 includes tap 1540 and base 1550. Tap 1540 includes tap potential 1542 (not shown) and tap contact 1544. Base 1550 includes base potential 1552 (not shown) and base contact 1554.

FIG. 16 illustrates a schematic circuit diagram of p-type channel triode capacitor apparatus 1500′, according to an exemplary embodiment. The embodiments of p-type channel triode capacitor apparatus 1500 shown in FIG. 15 and the embodiments of p-type channel triode capacitor apparatus 1500′ shown in FIG. 16 are similar. Similar reference numbers are used to indicate similar features of the embodiments of p-type channel triode capacitor apparatus 1500 shown in FIG. 15 and the similar features of the embodiments of p-type channel triode capacitor apparatus 1500′ shown in FIG. 16. Description of p-type channel triode capacitor apparatus 1500′ shown in FIG. 16 is omitted in the interest of brevity. One difference between the embodiments of p-type channel triode capacitor apparatus 1500 shown in FIG. 15 and the embodiments of p-type channel triode capacitor apparatus 1500′ shown in FIG. 16 is that p-type channel triode capacitor apparatus 1500′ includes series resistor 1556 with base current (I_{b}) 1558 between base potential (V_{dd}) 1552 and base node potential (V_{b}) 1560, complementary metal-oxide-semiconductor (CMOS) operational amplifier (op-amp) 1570 is connected to base node potential 1560 via control signal 1572, and gate 1512 is shown as proof-mass (m). Base potential 1552 varies as an impedance of p-type channel triode capacitor apparatus 1500′ changes. The impedance changes proportionally to a gap (i.e., gap 522 as shown in FIG. 5) between gate region 1510 and channel region 1530. As gate 1512 moves towards channel region 1530 (i.e., along X-axis), the gap becomes smaller and an electric field within the channel (i.e., electric field 520 as shown in FIG. 5) increases, which increases the impedance in channel region 1530 and causes base node potential 1560 to increase.

In some embodiments, p-type channel triode capacitor apparatus 1500′ can include a highly doped n-type gate region 1510 (e.g., N_{d}≈10²² cm⁻³), a lightly doped p-type channel region 1530 (Nₐ≈5×10¹⁴ cm⁻³), a lightly doped p-type substrate (i.e., substrate 502 as shown in FIG. 5) (Nₐ≈5×10¹⁴ cm⁻³), a gate potential 1514 of about 1.6 V, a base potential 1552 of about 0.8 V, a tap potential 1542 of about 0 V (i.e., ground), a gap (i.e., gap 522 as shown in FIG. 5) of about 2 μm, a channel region 1530 thickness of about 200 nm, and channel region 1530 electrically contacted to substrate (i.e., substrate 502 as shown in FIG. 5) on base contact 1554. For example, based on the above parameters, p-type channel triode capacitor apparatus 1500′ can achieve a voltage-to-gap sensitivity (σ) of about 0.5 V/μm to about 1.0 V/μm.

In some embodiments, p-type channel triode capacitor apparatus 1500′ can include a voltage-to-gap sensitivity (σ) of about 0.5 V/μm, a gate potential (V_{g}) 1514 of about 1.6 V, a base potential (V_{dd}) 1552 of about 1.6 V, a series resistor 1556 of about 800 kΩ, a base current (I_{b}) 1558 of about 1 μA, a base node potential (V_{b}) 1560 of about 0.8 V, a displacement amplitude of gate 1512 of about 200 nm, an output bandwidth of about 10 kHz, and a displacement root mean square (RMS) noise (i.e., resistive thermal noise) of about 0.0162 nm. For example, based on the above parameters, p-type channel triode capacitor apparatus 1500′ can achieve a signal-to-noise ratio (SNR) of about 201.8 dB. Note, a SNR of a perfect 32-bit sampler is 192.7 dB.

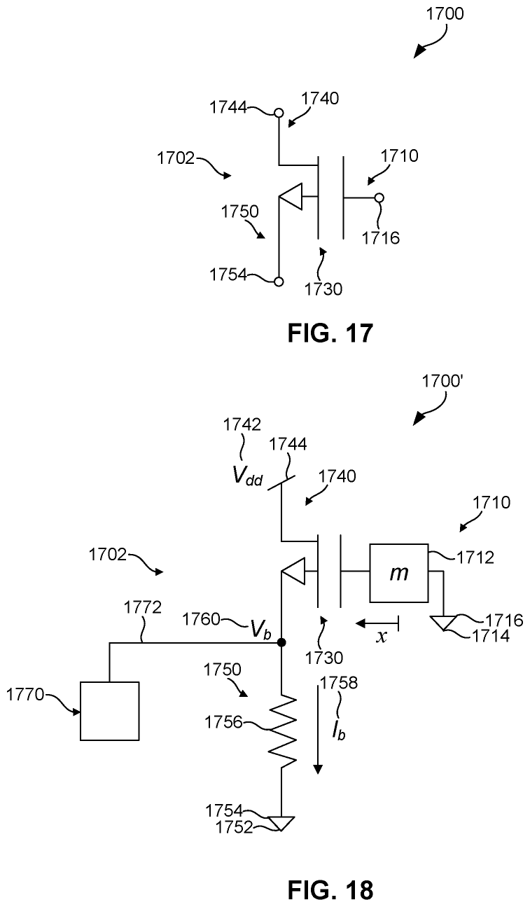

FIG. 17 illustrates a schematic circuit diagram of n-type channel triode capacitor apparatus 1700, according to an exemplary embodiment. The embodiments of triode capacitor apparatus 300 shown in FIGS. 3 and 4 and the embodiment of n-type channel triode capacitor apparatus 1700 shown in FIG. 17 are similar. The embodiments of sensor apparatus 500 shown in FIGS. 5 and 6 and the embodiment of n-type channel triode capacitor apparatus 1700 shown in FIG. 17 are similar.

Similar to triode capacitor apparatus 300 and sensor apparatus 500, n-type channel triode capacitor apparatus 1700 is configured to be a mechanically-gated diode 1702. As shown in FIG. 17, n-type channel triode capacitor apparatus 1700 includes gate region 1710 and n-type channel region 1730. Gate region 1710 includes gate 1712 (not shown), gate potential 1714 (not shown), and gate contact 1716. Gate region 1710 can be n-type (i.e., negative or zero gate potential 1714) or p-type (i.e., positive or zero gate potential 1714). Channel region 1730 includes tap 1740 and base 1750. Tap 1740 includes tap potential 1742 (not shown) and tap contact 1744. Base 1750 includes base potential 1752 (not shown) and base contact 1754.

FIG. 18 illustrates a schematic circuit diagram of n-type channel triode capacitor apparatus 1700′, according to an exemplary embodiment. The embodiments of n-type channel triode capacitor apparatus 1700 shown in FIG. 17 and the embodiments of n-type channel triode capacitor apparatus 1700′ shown in FIG. 18 are similar. Similar reference numbers are used to indicate similar features of the embodiments of n-type channel triode capacitor apparatus 1700 shown in FIG. 17 and the similar features of the embodiments of n-type channel triode capacitor apparatus 1700′ shown in FIG. 18. Description of n-type channel triode capacitor apparatus 1700′ shown in FIG. 18 is omitted in the interest of brevity. One difference between the embodiments of n-type channel triode capacitor apparatus 1700 shown in FIG. 17 and the embodiments of n-type channel triode capacitor apparatus 1700′ shown in FIG. 18 is that n-type channel triode capacitor apparatus 1700′ includes series resistor 1756 with base current (I_{b}) 1758 between base potential 1752 and base node potential (V_{b}) 1760, complementary metal-oxide-semiconductor (CMOS) operational amplifier (op-amp) 1770 is connected to base node potential 1760 via control signal 1772, and gate 1712 is shown as proof-mass (m). Base potential 1752 varies as an impedance of n-type channel triode capacitor apparatus 1700′ changes. The impedance changes proportionally to a gap (i.e., gap 522 as shown in FIG. 5) between gate region 1710 and channel region 1730. As gate 1712 moves towards channel region 1730 (i.e., along X-axis), the gap becomes smaller and an electric field within the channel (i.e., electric field 520 as shown in FIG. 5) increases, which increases the impedance in channel region 1730 and causes base node potential 1760 to increase.

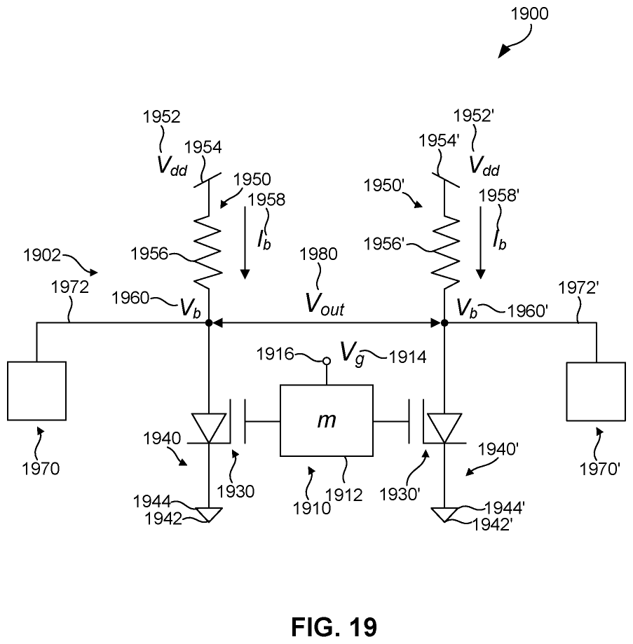

FIG. 19 illustrates a schematic circuit diagram of differential p-type channel triode capacitor apparatus 1900, according to an exemplary embodiment. The embodiments of p-type channel triode capacitor apparatus 1500′ shown in FIG. 16 and the embodiments of differential p-type channel triode capacitor apparatus 1900 shown in FIG. 19 are similar. Similar reference numbers are used to indicate similar features of the embodiments of p-type channel triode capacitor apparatus 1500′ shown in FIG. 16 and the similar features of the embodiments of differential p-type channel triode capacitor apparatus 1900 shown in FIG. 19. Description of differential p-type channel triode capacitor apparatus 1900 shown in FIG. 19 is omitted in the interest of brevity. One difference between the embodiments of p-type channel triode capacitor apparatus 1500′ shown in FIG. 16 and the embodiments of differential p-type channel triode capacitor apparatus 1900 shown in FIG. 19 is that differential p-type channel triode capacitor apparatus 1900 includes dual p-type channel triode capacitor apparatus 1500′ as shown in FIG. 16 (i.e., mirror image about gate 1912) with series resistor 1956, 1956′ with base current (I_{b}) 1958, 1958′ between base potential (V_{dd}) 1952, 1952′ and base node potential (V_{b}) 1960, 1960′, respectively, complementary metal-oxide-semiconductor (CMOS) operational amplifier (op-amp) 1970, 1970′ is connected to base node potential 1960, 1960′ via control signal 1972, 1972′, respectively, and gate 1912 is shown as proof-mass (m) for both first channel region 1930 and second channel region 1930′. Differential p-type channel triode capacitor apparatus 1900 can measure a differential base node potential (Vₒᵤₜ) 1980 between first base node potential 1960 and second base node potential 1960′.

For example, differential p-type channel triode capacitor apparatus 1900 shown in FIG. 19 can be arranged as sensor apparatus 700′ as shown in FIGS. 13 and 14 in order to differentially measure a distance of each gap 722, 722′ via differential base node potential 1980.

Exemplary Flow Diagram

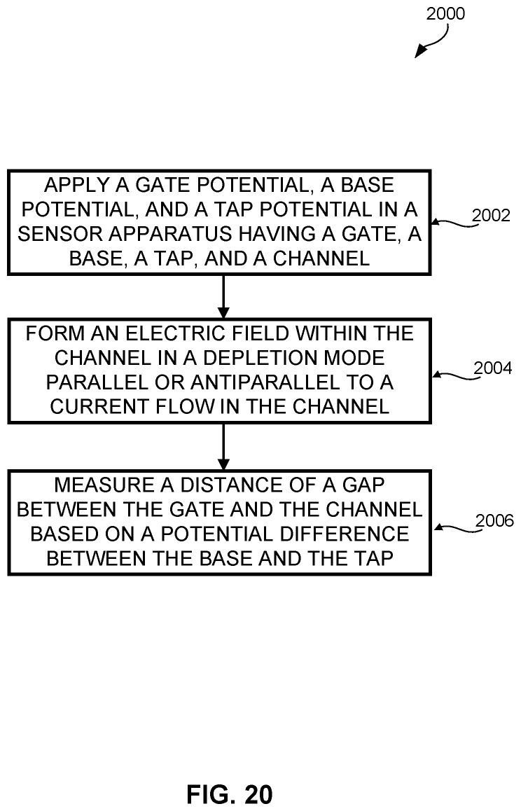

FIG. 20 illustrates flow diagram 2000 for measuring a distance of a gap between a gate region and a channel region in a sensor apparatus, according to an embodiment. It is to be appreciated that not all steps in FIG. 20 are needed to perform the disclosure provided herein. Further, some of the steps can be performed simultaneously, or in a different order than shown in FIG. 20. Flow diagram 2000 shall be described with reference to FIGS. 5, 6, and 16. However, flow diagram 2000 is not limited to those example embodiments.

In step 2002, as shown in the example of FIGS. 5 and 6, gate potential 514, base potential 552, and tap potential 542 are applied in sensor apparatus 500. For example, gate potential 514 of about 1.6 V, base potential 552 of about 0.8 V, and tap potential 542 of about 0 V (i.e., ground) can be applied. Sensor apparatus 500 includes channel region 530, gate region 510, gap 522, and processor 560. Channel region 530 includes base contact 554 and tap contact 544. Gate region 510 is adjacent channel region 530 and includes gate contact 516. Gate region 510 is separated from channel region 530 by gap 522. Processor 560 is coupled to base contact 554, tap contact 544, and gate contact 516.

In step 2004, as shown in the example of FIGS. 5 and 6, electric field 520 is formed within channel region 530 in a depletion mode, e.g., V_{g}>V_{b} for a p-type channel region 530 and an n-type gate 512, such that depletion region 524 is formed in channel region 530. At least portion 534 of charge flow 532 in channel region 530 is substantially parallel or antiparallel to electric field 520.

In step 2006, as shown in the example of FIGS. 5 and 6, a distance of gap 522 is measured by processor 560 based on a potential difference (i.e., base-tap potential 552, 542) between base contact 554 and tap contact 544.

In some embodiments, flow diagram 2000 further includes adjusting the distance of gap 522. For example, gate region 510 can include MEMS 526 and gate 512 can be adjusted along a vertical axis (i.e., Z-axis) perpendicular to an upper surface of channel region 530 (e.g., tap 540). In some embodiments, flow diagram 2000 further includes calculating an impedance of sensor apparatus 500 in real-time based on base potential 552. For example, base contact 554 can be connected in series with a resistor (e.g., resistor 1556 as shown in FIG. 16) and processor 560 can measure a base node potential (e.g., base node potential 1560 as shown in FIG. 16) within 0.2 seconds. In some embodiments, the applying includes holding gate potential 514, base potential 552, and tap potential 542 at 0 V (i.e., ground). In some embodiments, the measuring includes measuring the potential difference (i.e., base-tap potential 552, 542) between base contact 554 and tap contact 544 in real-time. For example, processor 560 can measure the potential difference (i.e., base-tap potential 552, 542) within 0.2 seconds.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some embodiments, the substrate itself may be patterned and materials added on top of it may also be patterned, or may remain without patterning.

Embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals, and others. Further, firmware, software, routines, and/or instructions may be described herein as performing certain actions. However, it should be appreciated that such descriptions are merely for convenience and that such actions in fact result from computing devices, processors, controllers, or other devices executing the firmware, software, routines, and/or instructions.

The following examples are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific embodiments of the invention have been described above, it will be appreciated that the invention may be practiced otherwise than as described. The description is not intended to limit the invention.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein.

The breadth and scope of the present invention should not be limited by any of the above-described exemplary embodiments, but should be defined only in accordance with the following claims and their equivalents.

What is claimed is:

1. A sensor apparatus comprising:
a base;
a tap adjacent the base and electrically coupled to the base;
a channel between the tap and the base; and
a gate adjacent the channel and electrically coupled to the channel, wherein the gate is separated from the channel by a gap,
wherein at least a portion of a charge flow in the channel is substantially parallel or antiparallel to an electric field between the gate and the channel.

2. The sensor apparatus of claim 1, wherein the gate comprises a microelectromechanical system (MEMS) configured to adjust the gap between the gate and the channel.

3. The sensor apparatus of claim 1, further comprising a processor coupled to the base, the tap, and the gate and configured to measure a distance of the gap between the gate and the channel based on a potential difference applied across the gap.

4. The sensor apparatus of claim 1, wherein, in a first configuration, the channel is in a depletion mode and the electric field pervades within the channel.

5. The sensor apparatus of claim 4, wherein the channel is a p-type semiconductor and a gate potential is greater than a channel potential.

6. The sensor apparatus of claim 4, wherein the channel is an n-type semiconductor and a channel potential is greater than a gate potential.

7. The sensor apparatus of claim 4, wherein a potential difference between the base and the tap is configured to be proportional to a distance of the gap between the gate and the channel.

8. The sensor apparatus of claim 4, wherein the base, the tap, and the gate are configured to operate in a low-power configuration and are each held at an applied potential of zero.

9. The sensor apparatus of claim 1, wherein the electric field is vertically oriented and configured to pervade the channel along a vertical axis.

10. The sensor apparatus of claim 1, wherein the electric field is horizontally oriented and configured to pervade the channel along a horizontal axis.

11. The sensor apparatus of claim 1, wherein the electric field is radially oriented and configured to pervade the channel along a radial axis.

12. The sensor apparatus of claim 1, wherein the sensor apparatus comprises an accelerometer, a gyroscope, a pressure sensor, a resonator, or a magnetometer.

13. The sensor apparatus of claim 1, wherein the gap comprises a dielectric.

14. A triode capacitor system comprising:
a channel region comprising a base contact and a tap contact;
a gate region adjacent the channel region and comprising a gate contact, wherein the gate region is separated from the channel region by a gap; and
a processor coupled to the base contact, the tap contact, and the gate contact and configured to measure a distance of the gap based on a potential difference between the base contact and the tap contact,
wherein at least a portion of a current flow in the channel region is substantially parallel or antiparallel to an electric field between the gate region and the channel region.

15. The triode capacitor system of claim 14, wherein the base contact is electrically connected to a first portion of the channel region and the tap contact is electrically connected to a second portion of the channel region separate from the first portion.

16. The triode capacitor system of claim 14, wherein:
the base contact is connected in series with a resistor; and
a base node between the resistor and the channel region is connected to a complementary metal-oxide-semiconductor (CMOS) operational amplifier (op-amp).

17. The triode capacitor system of claim 14, wherein the channel region is a p-type semiconductor and the gate region is an n-type semiconductor or a conductor.

18. A method for measuring a gap between a gate region and a channel region in a sensor apparatus, the method comprising:
applying a gate potential, a base potential, and a tap potential in the sensor apparatus, the sensor apparatus comprising:
a channel region comprising a base contact and a tap contact;
a gate region adjacent the channel region and comprising a gate contact, wherein the gate region is separated from the channel region by the gap; and
a processor coupled to the base contact, the tap contact, and the gate contact;
forming an electric field within the channel region in a depletion mode, wherein at least a portion of a current flow in the channel region is substantially parallel or antiparallel to the electric field; and
measuring, by the processor, a distance of the gap based on a potential difference between the base contact and the tap contact.

19. The method of claim 18, further comprising adjusting the distance of the gap, wherein the gate region comprises a microelectromechanical system (MEMS).

20. The method of claim 18, further comprising calculating an impedance of the sensor apparatus in real-time based on the base potential, wherein the base contact is connected in series with a resistor.
